(19) United States
(12) Patent Application Publication
(10) Pub. No.: US 2010/0018759 A1
(43) Pub. Date: Jan. 28, 2010

(54) ELECTRONIC DEVICE AND CIRCUIT BOARD

(75) Inventor: Toshio OE, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/356,033

(22) Filed: Jan. 19, 2009

(30) Foreign Application Priority Data
Jul. 24, 2008 (JP) 2008-191395

(51) Int. Cl. H05K 1/16

(52) U.S. Cl. 174/260

(57) ABSTRACT

According to one embodiment, an electronic device includes a housing, a circuit board housed in the housing, and a reinforcing member. The circuit board has a first surface and a second surface on the rear of the first surface. The first surface has a first electronic component mounted thereon. The second surface has a second electronic component mounted thereon at an opposite position of the first electronic component. The reinforcing member includes a base member and a bridge. The base member is provided on the second surface to reinforce a first mount area on which the first electronic component is mounted. The bridge passes through the first mount area, and extends, across and over the second electronic component, from at least two points on the base member.

### CROSS-REFERENCE TO RELATED APPLICATIONS

This application is based upon and claims the benefit of priority from Japanese Patent Application No. 2008-191395, filed Jul. 24, 2008, the entire contents of which are incorporated herein by reference.

### BACKGROUND

1. Field

One embodiment of the invention relates to an electronic device and a circuit board.

2. Description of the Related Art

In recent years, with an increased diversity of packaging for electronic components such as a semiconductor chip mounted on a circuit board, surface-mountable electronic components have been in widespread use. A surface-mountable electronic component does not require a lead or a pin for connection to a circuit board.

Among such surface-mountable electronic components is a ball grid array (BGA). The BGA is a leadless surface-mountable package, in which, for connection to external circuits, a plurality of electrodes (pads) are formed on the bottom thereof, and a solder ball is attached to each of the pads to constitute a connection terminal. The BGA is soldered onto a circuit board by heating through so-called reflow soldering with the solder ball being in contact with each of the pads of the circuit board.

When a portable electronic device including this circuit board is subjected to the impact of, for example, its fall, the circuit board may bend or warp due to the inertial force of the surface-mountable electronic component, etc. mounted thereon. In this case, stress is caused on the joint (soldered portion) between the surface-mountable electronic component and the circuit board, and accordingly, the solder may peel off. The circuit board bends substantially when the electronic device falls in the normal direction of the circuit board. In such cases, especially when the electronic device falls with the side having the surface-mountable electronic component mounted thereon facing down, a large stress is placed on the soldered portion, and the solder is more likely to peel off.

In view of this, Japanese Patent Application Publication (KOKAI) No. 2006-210852 discloses a conventional circuit board provided with a reinforcing plate. The reinforcing plate is arranged on the back of a surface-mountable electronic component with the circuit board between them. Specifically, the reinforcing plate is arranged on a side of the circuit board opposite the side on which the surface-mountable electronic component is mounted. The reinforcing plate is larger than the bottom surface of the surface-mountable electronic component to surround the portion corresponding to where the surface-mountable electronic component is mounted (hereinafter, “mount portion”)

In the conventional circuit board, the periphery of the mount portion is reinforced. On the other hand, no reinforcement is applied to the center of the mount portion, i.e., the direct back of the surface-mountable electronic component, which may result in insufficient suppression of the bending of the circuit board caused by the fall of the electronic device, etc. depending on the magnitude of the impact. Thus, the solder is likely to peel off.

There is another conventional technology for reinforcing the mount portion of a circuit board, in which the circuit board, a reinforcing plate, and a housing that houses the circuit board are screwed together. With this conventional technology, the center of the mount portion, i.e., the direct back of a surface-mountable electronic component, is also not reinforced. Therefore, when, for example, the electronic device falls, the bending of the circuit board may not be sufficiently suppressed, and the solder is likely to peel off. In addition, the screwing of the three parts imposes a restriction on the assembly of the electronic device.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the invention;

FIG. 2 is an exemplary schematic diagram of the inside of the housing of the portable computer in the first embodiment;

FIG. 3 is an exemplary perspective view of a reinforcing member to be attached to a circuit board in the portable computer in the first embodiment;

FIG. 4 is a cross-sectional view of the housing taken along the line F1-F1 of FIG. 2 in the first embodiment;

FIGS. 5 to 8 are exemplary perspective views of reinforcing members according to modifications of the first embodiment; and

FIG. 9 is an exemplary perspective view of a reinforcing member attached to a circuit board in a portable computer according to a second embodiment of the invention; and

FIG. 10 is a cross-sectional view of the housing taken along the line F1-F1 of FIG. 2 in the second embodiment.

### DETAILED DESCRIPTION

Various embodiments according to the invention will be described hereinafter with reference to the accompanying drawings. In general, according to one embodiment of the invention, an electronic device comprises: a housing; a circuit board contained in the housing, and has a first surface on which a first electronic component is mounted and a second surface formed on the reverse side of the first surface on which a second electronic component is mounted at an opposite position of the first electronic component; and a reinforcing member (a reinforcing frame) that comprises a base member provided on the second surface to reinforce a first mount area on which the first electronic component is mounted, and a bridge that passes through the first mount area, and extends, across and over the second electronic component, from at least two points on the base member.

According to another embodiment of the invention, a circuit board having a first surface and a second surface formed on the reverse side of the first surface, comprises: a first electronic component that is mounted on the first surface; a second electronic component that is mounted on the second surface at an opposite position of the first electronic component; and a reinforcing member that comprises a base member provided on the second surface to reinforce a first mount area on which the first electronic component is mounted, and a bridge that passes through the first mount area, and extends, across and over the second electronic component, from at least two points on the base member.

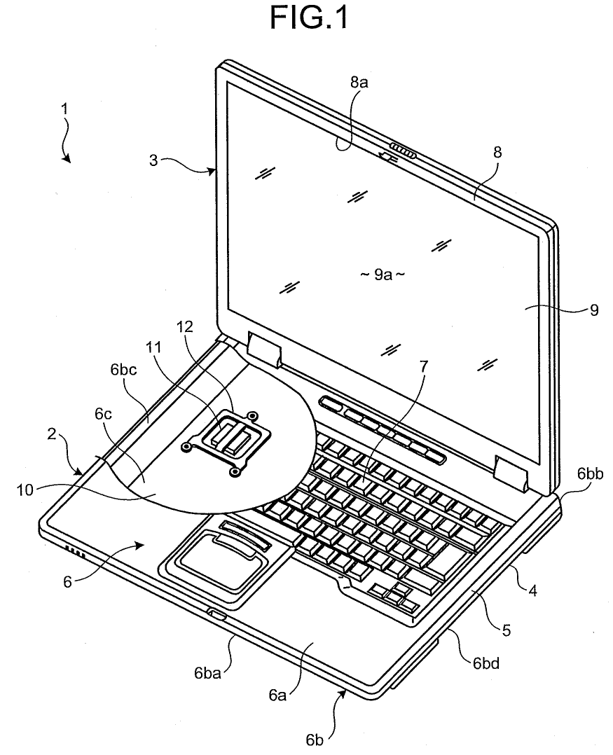

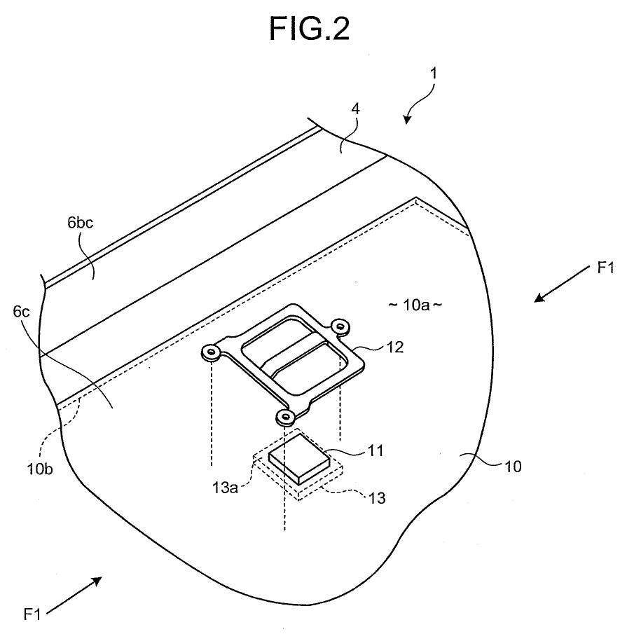

Described below is a configuration of a portable electronic device according to a first embodiment of the invention. The portable electronic device of the following embodiments will be described as a portable computer by way of example and without limitation; however, it can be other electronic devices, such as a digital camera, a video camera and a personal digital assistant, provided with a printed circuit board having a surface-mountable electronic component mounted thereon. FIG. 1 is a perspective view of a portable computer 1 according to the first embodiment. FIG. 2 illustrates the inside of a housing 6 of the portable computer 1.

The portable computer 1 of the first embodiment comprises a main body 2 and a display module 3.

The main body 2 comprises a base 4 and a cover 5. The cover 5 is fitted on the base 4. A combination of the base 4 and the cover 5 provides the main body 2 with the housing 6 formed in a box shape.

The housing 6 has a top wall 6a, a side wall 6b, and a bottom wall 6c. Supported on the top wall 6a is a keyboard 7. The side wall 6b includes a front side wall 6ba, a rear side wall 6bb, a left side wall 6bc and a right side wall 6bd.

The display module 3 comprises a display housing 8 and a liquid crystal display (LCD) panel 9 housed in the display housing 8. The LCD panel 9 is provided with a display screen 9a. The display housing 8 has an opening 8a on its surface so that the display screen 9a is exposed to the outside thereof through the opening 8a.

The display module 3 is hingedly supported on the rear edge of the housing 6. This allows the display module 3 to rotate between a closed position and an open position. The display module 3 lies and covers over the top wall 6a in the closed position, while it stands to expose the top wall 6a in the open position.

The housing 6 houses a printed circuit board 10, an electronic component 11, a reinforcing member 12, and a package 13.

The package 13 is a surface-mountable electronic component that does not require a lead or a pin for electrically connecting to a printed circuit board. The package 13 of the first embodiment is provided with a base having electrodes (pads) formed on the top and bottom surfaces thereof. An electronic component, i.e., a semiconductor chip, mounted on the top surface of the base is sealed in the package 13 with a resin material. The base is a circuit board, and the pads on the top surface, where the semiconductor chip is mounted, are each connected to an electrode of the semiconductor chip. The semiconductor chip is connected to the pads of the base by flip-chip bonding or wire bonding. The pads connected to the semiconductor chip are electrically connected to the pads arranged in a grid on the bottom surface of the base. A solder ball is attached to each of the pads arranged on the bottom surface of the base to form the package 13 as BGA circuit package.

Examples of the electronic component 11 include, but are not limited to, CPU, graphics chip, various chip sets, and memory.

The printed circuit board 10 of the first embodiment has a first mount surface 10b on which the package 13 is mounted. The rear of the first mount surface is a second mount surface 10a on which the electronic component 11 is mounted at a position corresponding to the package 13. The first mount surface 10b is the lower surface of the printed circuit board 10, and faces the bottom wall 6c. The package 13 is connected to the first mount surface 10b of the printed circuit board 10 via the solder balls attached to the pads arranged on the bottom surface of the base. On the other hand, the second mount surface 10a is the upper surface of the printed circuit board 10, and faces the top wall 6a. The electronic component 11 is mounted on the second mount surface 10a of the printed circuit board 10 at a position corresponding to the package 13 with leads, pins, or the like. Although not shown in the drawings, there may be mounted other components on the printed circuit board 10.

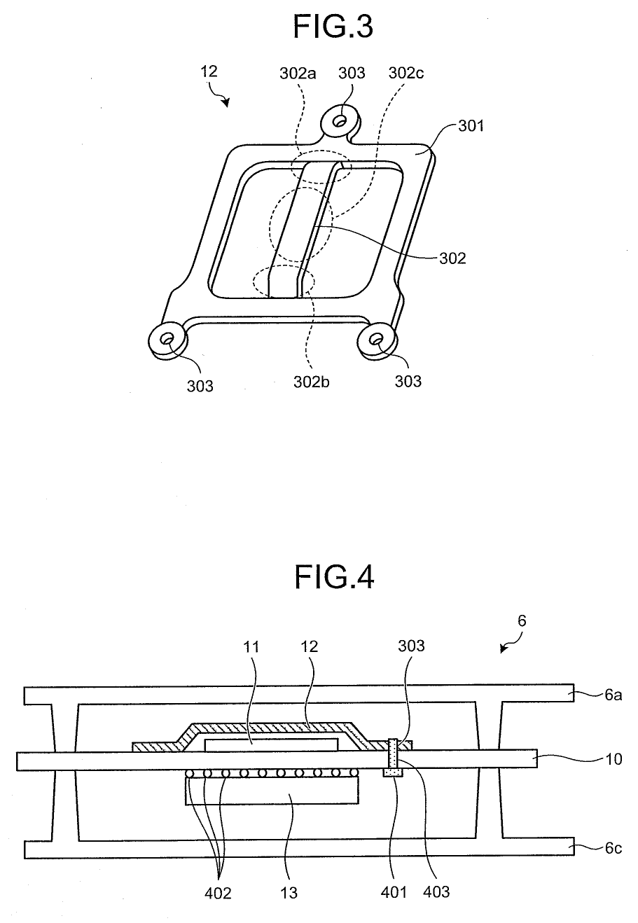

With reference to FIGS. 2 to 4, a description will be given of a specific configuration of the reinforcing member 12 and how to arrange it. FIG. 3 is a perspective view of the reinforcing member 12 to be attached to the printed circuit board 10 in the portable computer 1. FIG. 4 is a cross-sectional view of the housing 6 taken along the line F1-F1 of FIG. 2.

The reinforcing member 12 comprises a base member 301 that surrounds a projective area 13a on the second mount surface 10a. The projective area 13a is obtained by projecting the area occupied by the package 13 on the first mount surface 10b onto the second mount surface 10a. In other words, the projective area 13a is located on the second mount surface 10a and corresponds to the bottom surface of the base of the package 13 on the first mount surface 10b. Specifically, the base member 301 surrounds the projective area 13a in a substantially rectangular manner. If a plurality of packages (13) are arranged adjacent to each other on the first mount surface 10b of the printed circuit board 10, the base member 301 surrounds a projective area obtained by projecting an area occupied by the packages on the first mount surface lob onto the second mount surface 10a. Namely, the projective area corresponds to the bottom surfaces of the bases of the packages. For example, when two packages are mounted on the first mount surface 10b of the printed circuit board 10, the base member 301 surrounds a projective area obtained by projecting the bottom surfaces the bases of the two packages onto the second mount surface 10a.

The reinforcing member 12 further comprises a bridge 302 that passes through substantially the center of the projective area 13a. The bridge 302 extends, across and over the electronic component 11, from at least two points on the base member 301. The bridge 302 of the first embodiment extends between the centers of a pair of opposite sides of the base member 301 that surrounds the projective area 13a in a substantially rectangular manner, and passes through substantially the center of the projective area 13a. The bridge 302 comprises extending portions 302a and 302b, and a straight portion 302c. The extending portions 302a and 302b extend at an angle from the centers of the opposite sides of the base member 301, respectively, toward substantially the center of the projective area 13a. The straight portion 302c connects between the extending portions 302a and 302b in parallel with the second mount surface 10a, and extends over the electronic component 11 mounted on the second mount surface 10a. The form of the bridge 302 need not necessarily be as illustrated in FIGS. 3 and 4, and can be designed freely. For example, the bridge 302 may be formed into an arc extending from at least two points on the base member 301.

The base member 301 of the first embodiment is provided with three screw holes 303. In the printed circuit board 10 are formed through holes 403 that screws 401 pass through. In the first embodiment, first, the reinforcing member 12 is mounted on the second mount surface 10a so that the base member 301 surrounds the projective area 13a. Next, the position of the reinforcing member 12 is adjusted on the second mount surface 10a to align the screw holes 303 of the reinforcing member 12 with the through holes 403 formed in the printed circuit board 10, respectively. Then, the screws 401 are inserted through the through holes 403 from the first mount surface 10b side and are screwed into the screw holes 303, respectively. Thus, the reinforcing member 12 is mounted on the printed circuit board 10. Although, in the first embodiment, the reinforcing member 12 is provided with three screw holes (303), the number of the screw holes is given by way of example only and without limitation. For example, the reinforcing member 12 may have four screw holes each formed at one of the four corners thereof. The reinforcing member 12 of the first embodiment is made of, for example, metal with high hardness or resin.

As illustrated in FIG. 4, the package 13 of the first embodiment comprises solder balls 402 attached to the bottom surface of the base, and is connected to the first mount surface lob of the printed circuit board 10 via the solder balls 402. Thus, the package 13 is mounted on the printed circuit board 10.

As described above, according to the first embodiment, the portable computer 1 comprises the housing 6, the printed circuit board 10 housed in the housing 6, and the reinforcing member 12 attached to the printed circuit board 10. The printed circuit board 10 has the first mount surface lob and the second mount surface 10a on the rear of the first mount surface lob. The package 13 is mounted on the first mount surface lob, while the electronic component 11 is mounted on the second mount surface 10a at a position corresponding to the package 13. The reinforcing member 12 comprises the base member 301 that surrounds the projective area 13a obtained by projecting the area occupied by the package 13 on the first mount surface 10b onto the second mount surface 10a. The reinforcing member 12 further comprises the bridge 302 that passes through substantially the center of the projective area 13a. The bridge 302 extends, across and over the electronic component 11, from at least two points on the base member 301. With this, the center of a portion corresponding to the direct back of where the package 13 is mounted is reinforced, which allows the printed circuit board 10 to have improved resistance to bending. Thus, it is possible to sufficiently suppress the bending of the printed circuit board 10 which may be caused by, for example, the fall of the portable computer 1 depending on the magnitude of the impact. As a result, it is possible to prevent damage to the joint between the package 13 and the printed circuit board 10 such as the peel-off of the solder.

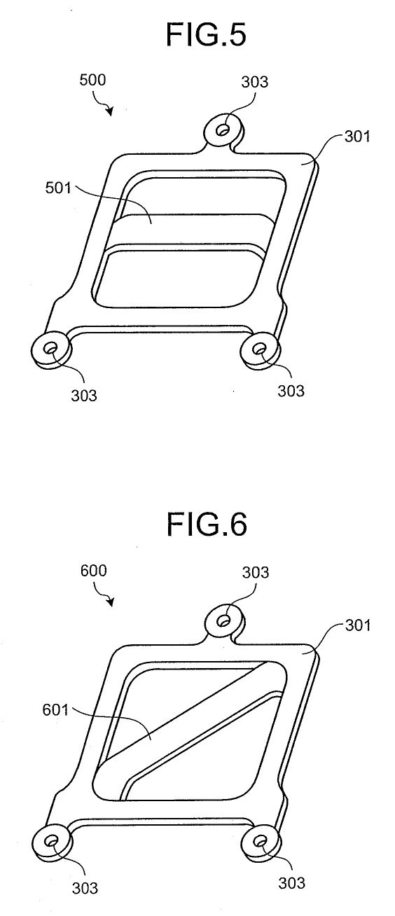

With reference to FIGS. 5 to 8, a description will be given of modifications of the reinforcing member 12 of the first embodiment. FIGS. 5 to 8 are perspective views of reinforcing members according to the modifications.

As with the reinforcing member 12 of FIG. 3 comprising the bridge 302, reinforcing members 500 and 600 illustrated in FIGS. 5 and 6 also include I-shaped bridges 501 and 601 extending over the electronic component 11, respectively. As illustrated in FIG. 5, the bridge 501 of the reinforcing member 500 extends in the direction perpendicular to the bridge 302 of the reinforcing member 12. As in the first embodiment, the bridge 501 extends between the centers of a pair of opposite sides of the base member 301 that surrounds the projective area 13a in a substantially rectangular manner, and passes through substantially the center of the projective area 13a. On the other hand, as illustrated in FIG. 6, the bridge 601 extends diagonally between a pair of opposite corners of the base member 301 that surrounds the projective area 13a in a substantially rectangular manner.

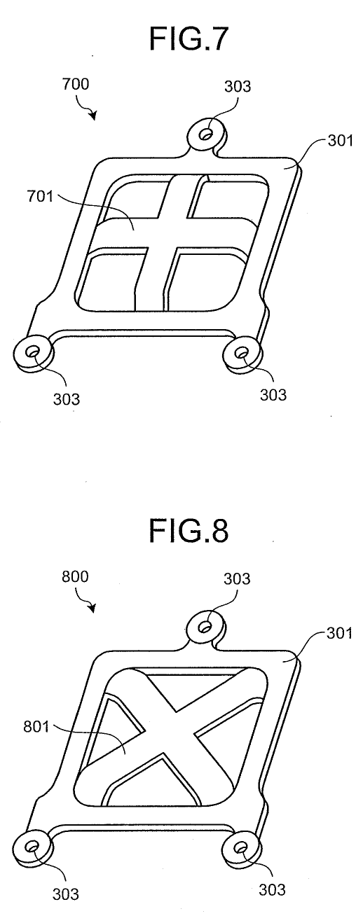

The bridge may extend over the electronic component 11 in a cross shape as bridges 701 and 801 of reinforcing members 700 and 800 illustrated in FIGS. 7 and 8. As illustrated in FIG. 7, the bridge 701 extends between the centers of two pairs of opposite sides of the base member 301 that surrounds the projective area 13a in a substantially rectangular manner, and passes through substantially the center of the projective area 13a. On the other hand, as illustrated in FIG. 8, the bridge 801 extends diagonally between two pairs of opposite corners of the base member 301 that surrounds the projective area 13a in a substantially rectangular manner.

In the portable computer 1 provided with any one of the reinforcing members 500, 600, 700 and 800 illustrated in FIGS. 5 to 8, a similar effect can be achieved as previously described in the first embodiment.

According to a second embodiment of the invention, the portable computer is provided with a reinforcing member comprising a bridge that is supported by the housing at substantially the center thereof. With this, it is possible to further suppress the bending of the printed circuit board which may be caused by, for example, the fall of the portable computer. The portable computer of the second embodiment is of like configuration as that of the first embodiment, and the same description will not be repeated.

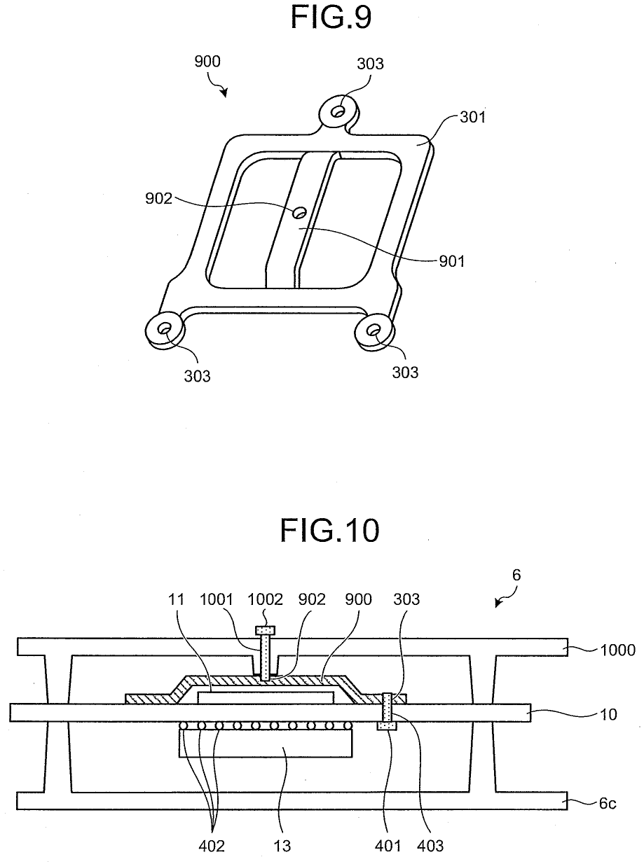

With reference to FIGS. 9 and 10, a description will be given of a specific configuration of the reinforcing member and how to arrange it. FIG. 9 is a perspective view of a reinforcing member 900 attached to the printed circuit board 10 in the portable computer 1 according to the second embodiment. FIG. 10 is a cross-sectional view of the housing 6 taken along the line F1-F1 of FIG. 2. The bridge 901 of the reinforcing member 900 is supported by the housing 6 at substantially the center thereof. In the center of the bridge 901 of the second embodiment, a screw hole 902 is formed perpendicularly to the second mount surface 10a. In a top wall 1000 of the housing 6 is formed a through hole 1001, which a screw 1002 passes through. The screw 1002 is inserted through the through hole 1001 from the outer side of the housing 6 and is screwed into the screw hole 902 in the bridge 901 of the reinforcing member 900. Thus, the bridge 901 is supported by the housing 6.

As described above, according to the second embodiment, the portable computer 1 is provided with the bridge 901 that is supported by the housing 6 (the top wall 1000). With this, the center of a portion corresponding to the direct back of where the package 13 is mounted is further reinforced, which allows the printed circuit board 10 to have further improved resistance to bending. Thus, it is possible to further suppress the bending of the printed circuit board 10 which may be caused by, for example, the fall of the portable computer 1. As a result, it is possible to prevent damage to the joint between the package 13 and the printed circuit board 10 such as the peel-off of the solder.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic device comprising:
a housing;
a circuit board in the housing comprising:
a first surface, on which a first electronic component is mounted, and
a second surface formed on a reverse side of the first surface, on which a second electronic component is mounted opposite to the first electronic component; and
a reinforcing frame comprising:
a base portion on the second surface configured to reinforce a first mounting area on which the first electronic component is mounted, and
a bridge configured to pass through the first mounting area, and extend from at least two points on the base portion across and over the second electronic component.

2. The electronic device of claim 1, wherein the bridge is supported by the housing at substantially center of the bridge.

3. The electronic device of claim 1, wherein the base portion surrounds the first mounting area in a substantially rectangular manner.

4. The electronic device of claim 3, wherein the bridge is configured to extend between diagonally opposite corners of the base portion in a substantially rectangular shape surrounding the first mounting area.

5. The electronic device of claim 3, wherein the bridge is configured to extend between opposite sides of the base portion in a substantially rectangular shape surrounding the first mounting area.

6. The electronic device of claim 1, wherein the bridge is cross-shaped.

7. The electronic device of claim 1, wherein the bridge is I-shaped.

8. A circuit board comprising a first surface and a second surface formed on a reverse side of the first surface, the circuit board comprising:
a first electronic component mounted on the first surface;
a second electronic component mounted on the second surface opposite to the first electronic component; and
a reinforcing frame that comprises
a base portion on the second surface configured to reinforce a first mounting area on which the first electronic component is mounted, and
a bridge configured to pass through the first mounting area, and to extend from at least two points on the base portion across and over the second electronic component.

9. The circuit board of claim 8 in a housing, wherein the bridge is supported by the housing at substantially center of the bridge.
